(19) United States
(12) Patent Application Publication
(10) Pub. No.: US 2025/0118637 A1
(43) Pub. Date: Apr. 10, 2025

(54) PACKAGE CARRIER WITH LARGE BACK SIDE AREA

(71) Applicant: Infineon Technologies AG, Neubiberg (DE)

(72) Inventors: Lee Shuang WANG, Bukit Baru (MY); Edward FÜRGUT, Dasing (DE); Arivindran NAVARETNASINGGAM, Seremban (MY)

(73) Assignee: Infineon Technologies AG, Neubiberg (DE)

(21) Appl. No.: 18/883,413

(22) Filed: Sep. 12, 2024

(30) Foreign Application Priority Data
Oct. 5, 2023 (DE) 10 2023 127 079.6

(51) Int. Cl. H01L 23/495; H01L 23/31; H01L 23/367

(52) U.S. Cl. CPC H01L 23/49568; H01L 23/3107; H01L 23/367; H01L 23/49541

(57) ABSTRACT

A carrier for carrying an electronic component of a package is disclosed. In one example, the carrier comprises a front side being provided with a horizontal component-sided area, and a back side opposing said front side and being provided with a horizontal back side area. A size of the horizontal back side area is larger than a size of the horizontal component-sided area.

### CROSS-REFERENCE TO RELATED APPLICATION

This Utility Patent Application claims priority to German Patent Application No. 10 2023 127 079.6 filed Oct. 5, 2023, which is incorporated herein by reference.

### BACKGROUND

### Technical Field

Various embodiments relate generally to a carrier, a package, an electronic device, and a method of manufacturing a carrier.

### Description of the Related Art

A package may be denoted as encapsulated electronic component with electrical connects extending out of the encapsulant. For example, packages may be connected to an electronic periphery, for instance mounted on a printed circuit board and/or connected with a heat sink, and may be connected via connectors to a larger system.

Power density is a key driver for the industry and enables new applications (e.g. aviation). Related with this are performance, dimensions and reliability. The different packaging solutions are manifold and have to address the needs of a specific application.

In particular packages with power semiconductor chip may generate a considerable amount of heat during operation. This may limit reliability and performance. Efficiently removing heat from the package may be accomplished by a heat sink or the like. At the same time, good electric performance of a package is required.

### SUMMARY

There may be a need for a package with efficient heat removal and/or high electric performance.

According to an exemplary embodiment, a carrier for carrying an electronic component of a package is provided, wherein the carrier comprises a front side being provided with a horizontal component-sided area, and a back side opposing said front side and being provided with a horizontal back side area, wherein a size of the horizontal back side area is larger than a size of the horizontal component-sided area.

According to an exemplary embodiment, a package is provided which comprises a carrier having the above-mentioned features, an electronic component mounted on at least part of the horizontal component-sided area of the carrier, and an encapsulant encapsulating at least part of the electronic component and at least part of the carrier.

According to another exemplary embodiment, an electronic device is provided, wherein the electronic device comprises a package having the above mentioned features, and a mounting structure mounted on, below or above the horizontal back side area.

According to yet another exemplary embodiment, a method of manufacturing a carrier for carrying an electronic component of a package is provided, wherein the method comprises providing the carrier with a front side with a horizontal component-sided area, providing the carrier with a back side opposing said front side and having a horizontal back side area, and forming a size of the horizontal back side area larger than a size of the horizontal component-sided area.

### BRIEF DESCRIPTION OF THE DRAWINGS

The accompanying drawings, which are included to provide a further understanding of exemplary embodiments and constitute a part of the specification, illustrate exemplary embodiments.

In the drawings:

FIG. 1 illustrates a schematic cross-sectional view of a package according to an exemplary embodiment, wherein the carrier is configured as a die pad.

FIG. 2 illustrates a flowchart of a method of manufacturing a carrier according to an exemplary embodiment.

FIG. 3 illustrates a schematic cross-sectional view of a package according to another exemplary embodiment.

FIG. 4 illustrates a schematic cross-sectional view of a carrier of a package according to an exemplary embodiment, wherein the carrier is configured as a die pad.

FIG. 5 illustrates a schematic cross-sectional view of a carrier of a package according to another exemplary embodiment.

FIG. 6 illustrates a cross-sectional view of an electronic device comprising a package according to an exemplary embodiment and being assembled with a heat sink-type mounting structure.

FIG. 7 illustrates a schematic cross-sectional view of a carrier of a package according to another exemplary embodiment.

FIG. 8 illustrates a schematic cross-sectional view of a carrier of a package according to another exemplary embodiment.

FIG. 9 illustrates a schematic cross-sectional view of a package according to another exemplary embodiment.

FIG. 10 illustrates a schematic cross-sectional view of a package according to another exemplary embodiment.

FIG. 11 illustrates a schematic cross-sectional view of parts of a package according to an exemplary embodiment, comprising a carrier configured as a clip.

### DETAILED DESCRIPTION

There may be a need for a package with efficient heat removal and/or high electric performance.

According to an exemplary embodiment, a carrier for carrying an electronic component of a package is provided, wherein the carrier comprises a front side being provided with a horizontal component-sided area, and a back side opposing said front side and being provided with a horizontal back side area, wherein a size of the horizontal back side area is larger than a size of the horizontal component-sided area.

According to an exemplary embodiment, a package is provided which comprises a carrier having the above-mentioned features, an electronic component mounted on at least part of the horizontal component-sided area of the carrier, and an encapsulant encapsulating at least part of the electronic component and at least part of the carrier.

According to another exemplary embodiment, an electronic device is provided, wherein the electronic device comprises a package having the above mentioned features, and a mounting structure mounted on, below or above the horizontal back side area.

According to yet another exemplary embodiment, a method of manufacturing a carrier for carrying an electronic component of a package is provided, wherein the method comprises providing the carrier with a front side with a horizontal component-sided area, providing the carrier with a back side opposing said front side and having a horizontal back side area, and forming a size of the horizontal back side area larger than a size of the horizontal component-sided area.

According to an exemplary embodiment, a carrier and a corresponding package equipped with such a carrier are provided, the carrier having a horizontal component-sided area on a front side and a horizontal back side area on an opposing back side. At least one electronic component may be mounted on the horizontal component-sided area of the carrier. The electronic component may be encapsulated partially or entirely and the carrier may be encapsulated partially or entirely by an encapsulant. This encapsulation may be accomplished in a way to expose at least part of the horizontal back side area with respect to the encapsulant so that the horizontal back side area is prepared for removing heat from the encapsulated electronic component and/or for providing an electric connection function. However, even when the entire carrier is encapsulated by the encapsulant, the horizontal back side area may also function for removing heat. Advantageously, a size or an amount of the horizontal back side area is made larger than a size or an amount of the horizontal component-sided area. This may ensure an efficient removal of heat created by the at least one electronic component during operation of the package via the enlarged horizontal back side area. Beneficially, the large horizontal back side area may lead not only to an enhanced amount of removed heat, but additionally also to heat spreading over an angular range from the encapsulated electronic component towards an exterior of the package. This may ensure, in turn, a proper performance of the package and a high thermal reliability. Additionally or alternatively, a bigger back side of a carrier may provide the additional advantage of conducting higher current or voltage. Further advantageously, a mounting structure (for example a heat sink or a printed circuit board) may be assembled directly or indirectly at the enlarged horizontal back side area for further promoting removal of heat out of an interior of the package and/or for conducting electric current.

### Description of Further Exemplary Embodiments

In the following, further exemplary embodiments of the carrier, the package, the electronic device, and the method will be explained.

In the context of the present application, the term “package” may particularly denote an electronic member which may comprise one or more electronic components mounted on one or more carriers, said at least one carrier to comprise or consist out of a single part, multiple parts joined via encapsulation or other package components, or a subassembly of carriers. Said constituents of the package may be encapsulated at least partially by an encapsulant.

In the context of the present application, the term “carrier” (for example a chip carrier) may particularly denote a support structure which serves as a mechanical support for one or more electronic components to be mounted thereon. In other words, the carrier may fulfil a mechanical support function. Additionally or alternatively, a carrier may also fulfill an electrical connection function. For this purpose, at least part of the carrier may be electrically conductive. A carrier may comprise or consist of a single part, multiple parts joined via encapsulation or other package components, or a subassembly of carrier sections. A carrier may also contribute to heat removal and heat spreading from the electronic component out of the package for promoting thermal dissipation. A metallic carrier, for instance comprising or consisting of copper and/or aluminum, may have a high thermal conductivity and may thus be excellent in terms of its heat removal capability. A sufficiently high heat capacity of a carrier may be advantageous as well. For example, a carrier may be a die pad (for instance of a leadframe structure) or may be a clip.

In the context of the present application, the term “electronic component” may in particular encompass a semiconductor chip (in particular a power semiconductor chip), an active electronic device (such as a transistor), a passive electronic device (such as a capacitance or an inductance or an ohmic resistance), a sensor (such as a microphone, a light sensor or a gas sensor), an actuator (for instance a loudspeaker), and a microelectromechanical system (MEMS). In particular, the electronic component may be a semiconductor chip having at least one integrated circuit element (such as a diode or a transistor) in a surface portion thereof. The electronic component may be a bare die or may be already packaged or encapsulated. Semiconductor chips implemented according to exemplary embodiments may be formed in particular in silicon technology, gallium nitride technology, silicon carbide technology, gallium oxide technology, etc. Particularly preferred may be one or more power semiconductor chips, chips manufactured from a wide bandgap semiconductor, etc.

In the context of the present application, the term “encapsulant” may particularly denote an electrically insulating and preferably thermally conductive material surrounding at least part of an electronic component and at least part of a carrier, and optionally of a part of one or more leads. For instance, the encapsulant may be a mold compound and may be manufactured for example by transfer molding or compression molding. Other encapsulation methods which can be implemented according to exemplary embodiments are printing, casting, glob-top formation, etc. It may also be possible that the encapsulant is of a gel-type, which may be used for encapsulating by potting.

In the context of the present application, the term “horizontal component-sided area” may in particular denote a surface portion of the carrier being oriented transverse or even perpendicular to a stacking direction of carrier and electronic component(s). When the package is assembled with a mounting structure below the package, the horizontal component-sided area may form the top main surface of a die-pad type carrier. When the package is assembled with a mounting structure below the package, the horizontal component-sided area may form the bottom main surface of a clip type carrier. Preferably, the horizontal component-sided area may be flat or planar. For example, the horizontal component-sided area may be free of a surface profile. Thus, the horizontal component-sided area may be a planar area. For example, the entire horizontal component-sided area may be a continuous area at a common vertical level. The horizontal component-sided area may comprise a central component mounting area on which the at least one electronic component is mounted or mountable. To avoid any misunderstanding, a carrier, e.g. a die pad of a lead frame, having some patterns or structures in its die attachment area, like grooves, recesses, reservoirs, spacers, e.g., for accommodating solder or glue or other adhesive material, should also be covered by the carrier in this patent application. Therefore in some scenarios, the horizontal component-sided area also may have one or more grooves, recesses, reservoirs, spaces, patterns and/or structures, etc. Additionally, the horizontal component-sided area may comprise a lateral, for instance annular, portion which may remain free of electronic component(s). For example, a width of such a lateral portion may be in a range from 100 μm to 1 mm. For instance, a main surface of an electronic component mounted on the horizontal component-sided area may have a surface area in a range from 10% to 80% of the entire surface area of the horizontal component-sided area, for example depending on requirements of a certain application. The horizontal component-sided area may form one entire (for instance upper) main surface of the carrier.

In the context of the present application, the term “horizontal back side area” may in particular denote an area of the carrier facing away from the horizontal component-sided area. In embodiments, the horizontal back side area may be exposed beyond the encapsulant, i.e. may not be covered by the encapsulant. In view of its exterior exposure, the horizontal back side area can guide heat and/or electric current created by the encapsulated electronic component(s) out of an interior of the package and towards an environment of the package. Optionally, this heat removal function may be supported by a mounting structure such as a heat sink, which may be attached to the horizontal back side area, preferably but not necessarily with a thermally conductive and electrically insulating layer in between. In other embodiments, the horizontal back side area may be encapsulated within the encapsulant. In particular, the horizontal back side area may be flat or planar. For example, the horizontal back side area may be free of a surface profile. The horizontal back side area may form the entire lower main surface of the carrier, or a central part thereof. In some embodiments, during molding process, some encapsulant may cover a small portion of the back surface of the carrier, e.g., so called mold flash. The horizontal back side area may refer to the area of the back surface of the carrier that is not covered by the mold flash. For example, the horizontal back side area is a planar area or is a stepped area.

In the context of the present application, the term “size of the horizontal back side area” may in particular denote the amount of horizontally oriented carrier surface area defined by the horizontal back side area which is exposed with respect to the encapsulant and which is covered by the encapsulant. For instance, the size of the horizontal back side area may be given in square centimeters. For example, the horizontal back side area may be a polygonal (for instance rectangular) or round (for instance circular) surface area.

In the context of the present application, the term “size of the horizontal component-sided area” may in particular denote the amount of carrier surface area defined by the horizontal component-sided area. For instance, the size of the horizontal component-sided area may be given in square centimeters. For example, the horizontal component-sided area may be a polygonal (for instance rectangular) or round (for instance circular) surface area.

In the context of the present application, the term “main surface” of a body may particularly denote a body surface of one of the largest body surfaces. For instance, a body (such as a carrier or part thereof) may be plate-shaped or substantially plate-shaped and may then have two opposing main surfaces separated by body material in a thickness direction and connected with each other by a circumferential sidewall or edge. For example, one main surface of a carrier body may be at least partially exposed. Additionally or alternatively, one main surface (for instance another main surface) of a carrier body may be connected to one or more chips. For example, a front side surface and a back side surface of a carrier may form two opposing main surfaces thereof.

In an embodiment, the mounting structure comprises a heat sink or a mounting base (for example a printed circuit board (PCB) or an insulated metal substrate (IMS) or a Direct Copper Bonding (DCB) substrate or an Active Metal Brazing (AMB) substrate). As an alternative to a printed circuit board, also another kind of laminate carrier may be implemented. In the context of the present application, the term “heat sink” may in particular denote a highly thermally conductive body which may be thermally coupled with the package and in particular the carrier of the package for removing heat generated by the electronic component during operation of the package. For example, the heat sink may be made of a material having a thermal conductivity of at least 10 W/mK, in particular at least 50 W/mK, even up to 400 W/mK or even above. For instance, the heat sink may be made of an electrically conductive material such as copper and/or aluminum, but may also comprise a ceramic material. The heat sink may be directly or indirectly thermally coupled with the partially exposed carrier, for instance by a thermally conductive and electrically insulating layer, such as a thermal interface material (TIM) and/or a gap filler. For instance, the thermally conductive and electrically insulating layer may have a thermal conductivity in a range from 3 W/mK to 20 W/mK, or even above. For example, the heat sink may comprise a thermally conductive body (such as a metal plate) with a plurality of cooling fins extending from the thermally conductive body. Additionally or alternatively, liquid and/or gas cooling may be accomplished by a heat sink as well. The thermal coupling of the package with a heat sink may ensure an efficient cooling. In the context of the present application, the term “printed circuit board” may in particular denote a flat body (such as a sheet or plate) formed by multiple interconnected laminate layers, i.e. electrically insulating and electrically conductive layers, which can be or which are interconnected by lamination. Lamination may denote a connection of laminable layers using elevated temperature, optionally accompanied by an additional mechanical pressure applied to stacked laminate layers. In the context of the present application, the term “insulated metal substrate” may in particular denote a printed circuit board built on a metal plate (for instance made of aluminium) on which an electrically insulating layer, for example of prepreg, is applied.

When, in a preferred embodiment, the mounting structure is embodied as heat sink, the heat sink may be mechanically and thermally coupled with the horizontal back side area by a thermally conductive and electrically insulating layer (for instance a gap filler or a thermal interface material) in between. While such a thermally conductive and electrically insulating layer may ensure electrical isolation of a metallic horizontal back side area, its thermal conductivity may be significantly lower than that of heat sink and carrier. Thus, the increase of an exposed heat removal area of the horizontal back side area as achieved by exemplary embodiments may be of utmost advantage when implementing a thermally conductive and electrically insulating layer between heat sink and partially exposed carrier. Also when the carrier is fully encapsulated by the encapsulant or is mounted on an interposer being exposed beyond the encapsulant, a heat sink may be attached to the encapsulant or the interposer for additionally promoting heat removal.

When, in an alternative embodiment, the mounting structure is embodied as a PCB or an IMS, such a mounting structure may be connected with the (for example exposed) horizontal back side area for instance by soldering, sintering, by electrically conductive glue or another electrically conductive connection medium. A PCB or IMS may promote heat removal without thermally conductive and electrically insulating layer in between, and may also have an electric coupling function for the encapsulated electronic component(s) of the package.

In an embodiment, a vertical thickness of the carrier may be in a range from 200 μm to 2 mm. The larger the thickness of the carrier (for instance a die pad), the larger may be the gain of dissipated heat. Descriptively speaking, the thicker the carrier, the larger will be the area increase on the back side at a certain sidewall slanting angle. Such a tapering of the carrier may increase the amount of metal which may further increase the heat capacity of the carrier. A corresponding carrier may also tackle short events.

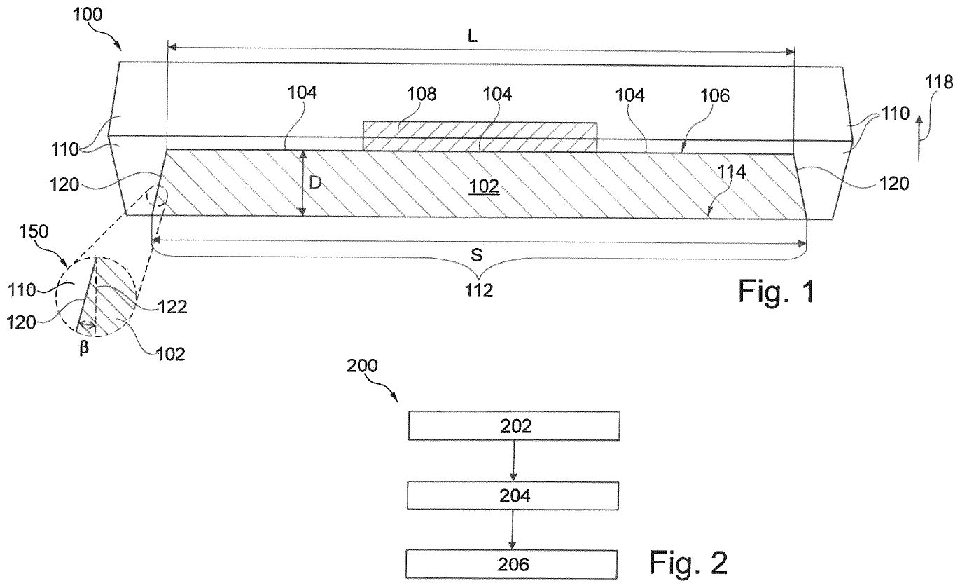

In one embodiment, a size of an exposed heat removal area of the horizontal back side area may be larger than a size of the horizontal component-sided area (see for example FIG. 1). This may lead to excellent heat removal properties. For instance, the bottom main surface of the carrier may be free of an anti-flash profile in such an embodiment.

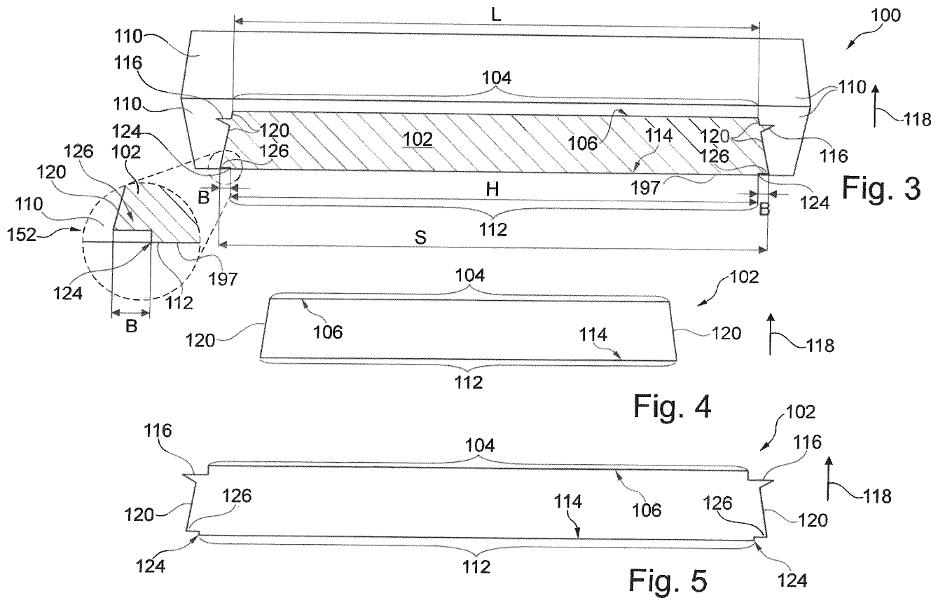

In another embodiment, a size of an exposed heat removal area of the horizontal back side area may be the same as a size of the horizontal component-sided area (see for example FIG. 3). For instance, an outermost portion of the bottom main surface of the carrier may be provided with an anti-flash profile in such an embodiment. At the same time, very good heat removal properties may be obtained.

In an embodiment, at least part of a sidewall of the carrier tapers in a thickness direction from the back side towards the front side. To put it shortly, sidewalls of the carrier may be partially or entirely slanted rather than being completely vertical. In particular, a die pad-type carrier (or a clip-type carrier) may be provided with angled sidewalls. For instance, such a shape may be manufactured by angled punching. A tapering sidewall of the carrier may advantageously increase the horizontal back side area in comparison with the horizontal component-sided area. Furthermore, a slanted leadframe die pad sidewall or a slanted clip sidewall may also promote heat spreading inside the carrier. For instance, heat may spread over an angle of approximately ±45°. Such a heat spreading may be promoted by tapering sidewalls of the carrier connecting the horizontal component-sided area with the horizontal back side area.

In an embodiment, the at least partially tapering sidewall of the carrier has a straight shape (see for instance FIG. 1). A straight shape may be formed with a particularly simple manufacturing process, for instance by punching.

In an embodiment, a tapering angle of the sidewall of the carrier relative to a vertical direction is at least 5°. Additionally or alternatively, a tapering angle of the sidewall of the carrier relative to a vertical direction is not more than 45°. Preferably, said tapering angle may be in a range from 5° to 30°, in particular in a range from 10° to 25°. The mentioned tapering angles may allow to provide a significantly large increase of the horizontal back side area compared with the horizontal component-sided area without rendering the manufacturing process excessively complex and without the risk of pronounced manufacturing artefacts, such as burrs.

In an embodiment, a first part of the sidewall tapers in the thickness direction and a connected second part of the sidewall extends vertically along the thickness direction. Such an embodiment is shown in FIG. 8. An edge or corner may be formed between the first part and the second part. The vertical second part may have the advantage that it may efficiently suppress undesired manufacturing artefacts, such as burrs and/or particles created by abrasion due to sidewall processing.

In an embodiment, at least part of a sidewall of the carrier has a stepped profile narrowing from the back side towards the front side. Such an embodiment is shown for instance in FIG. 7. When the sidewall of the carrier has a stepped profile, a single step may be present, or a plurality of steps may be formed in a stairway-type fashion. The steps may contribute to a mechanical anchoring of the carrier in the encapsulant. At the same time, the steps may lead to a spatial widening from front side to back side to thereby increase the horizontal back side area in comparison with the horizontal component-sided area.

In an embodiment, the carrier is formed as at least part of a leadframe structure, in particular as a die pad. More generally, the carrier may comprise or consist of a patterned metal plate (for instance made of copper and/or aluminum). In the context of the present application, the term “leadframe” may particularly denote a sheet-like metallic structure which can be bent, punched and/or patterned so as to form leadframe bodies as mounting sections for mounting chips, and connection leads for electric connection of the package to an electronic environment. In an embodiment, the leadframe may be a metal plate (in particular made of copper) which may be patterned, for instance by stamping. Forming the chip carrier as a leadframe is a cost-efficient and mechanically as well as electrically highly advantageous configuration in which a low ohmic connection of chips can be combined with a robust support capability of the leadframe. Furthermore, a leadframe may contribute to the thermal conductivity of the package and may remove heat generated during operation of the chip(s) as a result of the high thermal conductivity of the metallic (in particular copper) material of the leadframe.

In an embodiment, the carrier additionally comprises at least one lead section separate from the die pad. (see FIG. 11) In particular, an array of lead sections may be provided which may form, together with a die pad, a leadframe structure.

In another embodiment, the carrier is formed as clip. A “clip” may particularly denote a connection element which comprises an electrically conductive material such as copper and is an integral body. A clip may be connected to a main surface (preferably to an upper main surface) of an electronic component, such as a semiconductor die. For example, an electronic component configured as semiconductor die may be sandwiched between a die pad on a bottom side and a clip on a top side.

In an embodiment, a difference between a diameter (for instance a maximum diameter) of the horizontal back side area and a diameter (for instance a maximum diameter) of the horizontal component-sided area is at least 0.5 mm. Additionally or alternatively, a difference between a diameter (for instance a maximum diameter) of the horizontal back side area and a diameter (for instance a maximum diameter) of the horizontal component-sided area is not more than 5 mm. The exact dimensions may depend on a certain application. As mentioned above, the horizontal back side area may be larger than the horizontal component-sided area.

In an embodiment, a difference between the horizontal back side area and the horizontal component-sided area divided by the horizontal back side area is at least 3%. Additionally or alternatively, a difference between the horizontal back side area and the horizontal component-sided area divided by the horizontal back side area may be not more than 30%. For instance, said ratio may be in a range from 5% to 15%. In a rough approximation, the amount of removable heat scales with the increased area of the horizontal back side area. In the above example, the amount of removable heat may be increased by about 5% to 15%. As mentioned above, the horizontal back side area may be larger than the horizontal component-sided area.

In an embodiment, the carrier has a step at the back side to thereby form a retracted lateral section surrounding a protruding central area. For instance, the carrier has a step at the back side between an exposed central main heat removal area and a retracted lateral encapsulated section surrounding the exposed main heat removal area. Such an embodiment is shown for instance in FIG. 3. Descriptively speaking, such a step may define or limit the position of mold flash. In such an embodiment, the exposed main heat removal area of the horizontal back side area may be a central area of the back side of the carrier. The retracted lateral section may laterally surround said central area and may be retracted or displaced towards the front side with respect to said central area. While the main heat removal area may be exposed with respect to the encapsulant, the lateral section may be covered by material of the encapsulant. By the mentioned step at the back side of the carrier laterally surrounding the exposed heat removal area of the carrier, an anti-flash profile may be generated which may suppress or even prevent undesired mold flash phenomena.

In an embodiment, a sidewall of the carrier is provided with an outwardly oriented spike. Such an embodiment is shown for instance in FIG. 3. Advantageously, such a spike may function as a mold interlocking feature. Descriptively speaking, such a mold interlocking feature may function as a mechanical anchor between the carrier and the encapsulant. For instance, such a spike may be formed by coining.

In particular, the mentioned mold interlocking feature and/or anti-flash profile as well as measures for controlling punching-caused burrs, etc., may be refinements relating to fine-conditioning of the carrier geometry. Such measures may not have a significant impact on an area modification of the carrier. In particular, such refinement techniques may be executed by coining.

In an embodiment, the carrier comprises a die pad, on which the electronic component is arranged, and a lead section (which may be separate from the die pad) electrically coupled with the die pad and/or the electronic component. Thus, the package may comprise one or more leads which are electrically coupled with the electronic component. In the context of the present application, the term “lead” may in particular denote an electrically conductive (for instance strip shaped) element (which may be planar or bent) which may serve for contacting the electronic component with an exterior of the package. For instance, a lead may be partially encapsulated and partially exposed with respect to an encapsulant. In particular, leads may extend out of one or more side walls of the encapsulant.

In an embodiment, the horizontal back side area is partially (see for instance FIG. 3) or entirely (see for instance FIG. 1) exposed beyond the encapsulant. Such an exposed area may function for promoting heat removal and/or for conducting electricity.

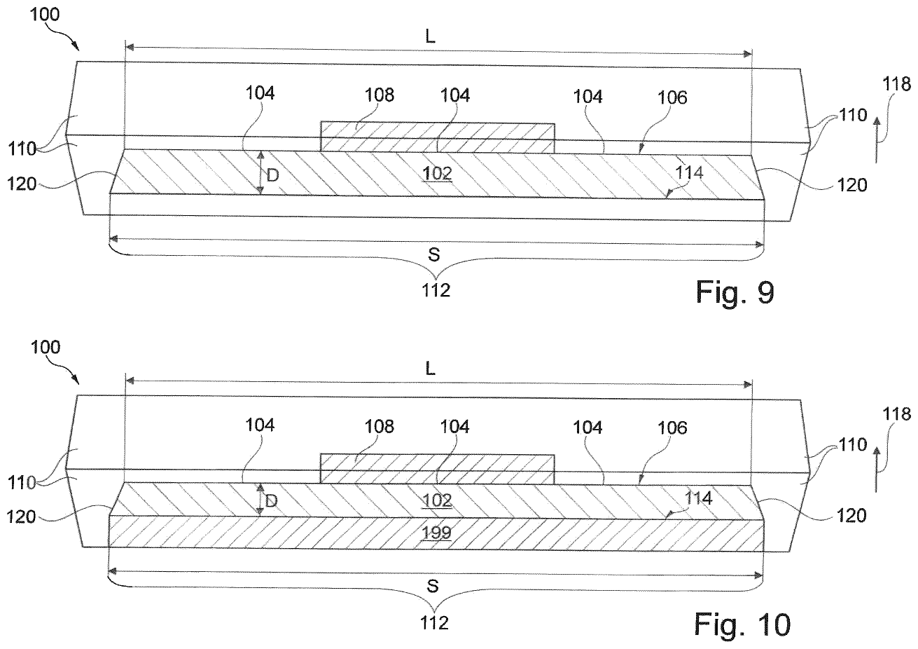

In an embodiment, the horizontal back side area is fully encapsulated within the encapsulant (see for instance FIG. 9). Via the horizontal back side area and a thin encapsulant layer below it, heat may then be removed.

In an embodiment, the package comprises an interposer on the horizontal back side area of the carrier and being exposed beyond the encapsulant (see for instance FIG. 10). For instance, such an interposer may be a ceramic sheet covered on both opposing main surfaces thereof with a metal sheet (which may be continuous or patterned). Such an interposer may contribute to the removal of heat from the electronic component via the carrier and the interposer towards an environment.

In an embodiment, the horizontal back side area is configured for removing heat generated by the electronic component during operation of the package (see for instance FIG. 1 or FIG. 3). In particular when exposing the carrier with respect to the encapsulant, this heat dissipation may be very efficient. Thus, the enlarged back side area may have a thermal function and may allow an increased amount of heat to be removed.

In an embodiment, the horizontal back side area is configured for electrically coupling the electronic component with an exterior of the package (for instance when the package is mounted on a PCB and an exposed carrier is electrically coupled with a pad on a surface of the PCB). Hence, the enlarged back side area may have an electric function and may allow an increased amount of current or voltage to be handled.

In an embodiment, a size of an area of the horizontal back side area being exposed beyond the encapsulant is the same as (see FIG. 3) or is larger than (see FIG. 1) the size of the horizontal component-sided area. In the first mentioned scenario, an anti-mold flash retracted area may be within the encapsulant. In the second mentioned scenario, the back side may be entirely exposed beyond the encapsulant.

In an embodiment, the package comprises only a single electronic component. Alternatively, the package comprises a plurality of electronic components mounted on at least part of the horizontal component-sided area. For instance, such electronic components may be arranged side-by-side on the horizontal component-sided area. Different electronic components may be of the same type or of different types. Different electronic components may have the same size or different sizes. For instance, the different electronic components may be semiconductor chips, in particular power semiconductor chips. It is for instance possible to provide a mixture of at least one IGBT-type electronic component and at least one silicon carbide-type electronic component.

In an embodiment, the electronic device comprises a thermally conductive and electrically insulating layer between the mounting structure, when formed as a heat sink, and the horizontal back side area being preferably at least partially exposed beyond the encapsulant. In an embodiment, the electrically insulating material is arranged at an interface between the heat sink-type mounting structure and the package. In another words, the electrically insulating material may electrically decouple the carrier with respect to the heat sink. Preferably, the electrically insulating material has additionally thermally conductive properties (in particular a thermal conductivity of at least 2 W/mK) for efficiently contributing to a heat removal from the electronic component towards the heat sink. In an embodiment, the electrically insulating material covering the electrically conductive material of the carrier and thereby spacing the electrically conductive material with respect to the heat sink may have a thickness in a range from 100 μm to 2 mm, in particular in a range from 100 μm to 1 mm, more particularly in a range from 100 μm to 600 μm. This may ensure a proper mutual isolation while nevertheless guaranteeing a proper thermal coupling with the heat sink.

In an embodiment, forming the size of the horizontal back side area larger than the size of the horizontal component-sided area is carried out by treating sidewalls of the carrier by coining and/or punching. These processing technologies may allow to precisely define one or more sidewall features in a fast and simple way. Other manufacturing methods may be executed as well.

In an embodiment, the carrier comprises leadframe. However, the carrier may also be a Direct Copper Bonding (DCB) substrate or a Direct Aluminium Bonding (DAB) substrate. However, the carrier may also be configured as Active Metal Brazing (AMB) substrate, or as Insulated Metal Substrate (IMS).

In an embodiment, the package is configured as power package. A power package may be a package comprising at least one power chip as encapsulated electronic component. Thus, the package may be configured as power module, for instance molded power module such as a semiconductor power package. For instance, an exemplary embodiment of the package may be an intelligent power module (IPM). Also a Smart IPM is possible (including a microcontroller). The package may also provide connectivity features, for instance WiFi, Bluetooth, etc. Another exemplary embodiment of the package is a dual inline package (DIP). Also SMD (surface mounted device) packages, packages with top-sided cooling, packages with bottom-side cooling, and packages with double-sided cooling may be implemented according to exemplary embodiments.

Correspondingly, the electronic component may be configured as a power semiconductor chip. Thus, the electronic component (such as a semiconductor chip) may be used for power applications for instance in the automotive field and may for example have at least one integrated insulated-gate bipolar transistor (IGBT) and/or at least one transistor of another type (such as a MOSFET, a JFET, a HEMT, etc.) and/or at least one integrated diode. Such integrated circuit elements may be manufactured for instance in silicon technology or based on wide-bandgap semiconductors (such as silicon carbide, gallium nitride). A semiconductor power chip may comprise one or more field effect transistors, diodes, inverter circuits, half-bridges, full-bridges, drivers, logic circuits, further devices, etc. Advantages of exemplary embodiments concerning enhanced thermal performance are particularly pronounced for power dies. Also in the context of driver technologies which are handling high voltages (for example an insulated gate driver, level shifter gate drivers, solid state relays, circuit breakers, etc.), exemplary embodiments may provide significant advantages.

As substrate or wafer for the semiconductor chips, a semiconductor substrate, for example a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology.

The above and other objects, features and advantages will become apparent from the following description and the appended claims, taken in conjunction with the accompanying drawings, in which like parts or elements are denoted by like reference numbers.

The illustration in the drawing is schematically and not to scale.

Before exemplary embodiments will be described in more detail referring to the figures, some general considerations will be summarized based on which exemplary embodiments have been developed.

Discrete power devices are determined by heat dissipation which are heavily related in some cases (for example surface mounted device (SMD) top side cooling) to the area of an exposed die pad. On the other side, the encapsulation (for example a mold compound applied by transfer molding) shall maintain a sufficiently small gap between die pad and mold body to ensure a proper filling and robustness. Therefore, a maximum die pad size is determined by a conventional encapsulation assembly design rule.

In conventional packages, an exposed heat sink area is always smaller than the die pad size. This involves a significant limitation concerning thermal reliability and performance, in particular for packages with wide bandgap semiconductor chip(s), for instance formed in silicon carbide technology. In particular for wide bandgap semiconductor chips, every inch of the heat sink is important for the performance of the package. Hence, mold flash features may take up a significant area of the heat sink, impacting thermal resistance-related performance of the package.

According to an exemplary embodiment, a carrier and a corresponding package with such a carrier is provided, which may be at least partially electrically conductive (for instance may be or may comprise a metallic die pad). At least part of a horizontal component-sided area on a front side of the carrier may be configured for accommodating and mounting at least one electronic component thereon. A horizontal back side area may be formed on a back side of the carrier opposing said front side. Descriptively speaking, horizontal component-sided area and horizontal back side area may form two opposing main surfaces of the carrier. One or more electronic components (for instance one or more power semiconductor chips) may be mounted on the horizontal component-sided area of the carrier, for instance by soldering (such as diffusion soldering or soft soldering), sintering or gluing. Both the at least one electronic component and the carrier may be covered by an encapsulant. The above mentioned horizontal back side area of the carrier may be used for promoting thermal coupling between an interior and an exterior of the package and/or for providing an electric coupling function. Beneficially, a size of the horizontal back side area is made larger than a size of the horizontal component-sided area (see for instance FIG. 1) As a consequence, the heat removal capability of the package may be enhanced, since an exterior area over which heat may be directly dissipated from the package towards an environment is rendered as large as or even larger than the horizontal component-sided area having a central part on which the electronic component may be mounted. This can be achieved by an appropriate design of the carrier which may be provided for example with a sidewall shaping extending laterally outwardly in a direction from the horizontal component-sided area towards the horizontal back side area. By taking this measure, the heat removal capacity and additionally a heat spreading functionality may be strongly enhanced. Thus, heat created by the at least one electronic component during operation of the package may be dissipated efficiently via the enlarged horizontal back side area while achieving simultaneously a beneficial heat spreading over a broader angular range. Additionally or alternatively, the enlarged horizontal back side area may fulfil a powerful electric coupling function allowing high current values in view of the large area size on the back side. A correspondingly designed package may provide a high performance, a high thermal reliability and also a high electric reliability thanks to the proper coverage of carrier and electronic component with encapsulant material. When a heat sink (or another appropriate mounting structure) is assembled on the enlarged horizontal back side area, heat removal can be further improved over a broad spatial range.

According to an exemplary embodiment, the heat sink-related area of the package may be bigger than the die pad size. This may be accomplished by flexibly engineering a sidewall angle of the die pad. Advantageously, this may provide a bigger margin for anti-mold flash and may allow to improve or even optimise thermal resistance-related performance.

In particular, it may be possible to provide a tapering die pad (with freely adjustable tapering angle). This may allow to obtain a large heat sink size which may lead, in turn, to an efficient heat removal. For example, a carrier (such as a die pad) with trapezoidal cross-sectional shape may be provided for this purpose. A carrier with tapering sidewall may be formed for example by punching, stamping and/or coining, or by any other appropriate sidewall processing method. This may allow to achieve a bigger exposure of a die pad-type carrier facing an exterior heat sink. In particular, it may be possible to improve or even optimize a die pad to heat sink interface spatially in a limited package space due to mold wall robustness versus thermal resistance requirements of a package.

A die pad/heat sink coupling area may be extended, for instance in a range from 5% to 20%. This may allow to at least partially compensate the space used for an anti-mold flash profile.

An obtainable increase of an exposed heat sink area may be highly advantageous, since this may allow to increase the power density and/or reduce the size of the electronic component(s). A corresponding chip shrink may be of utmost advantage especially for wide band gap devices (for example in SiCMOS or GaN technology). Semiconductor chips manufactured based on wide bandgap semiconductors have a small size and a high power density in comparison with conventional silicon chips. Thus, maximizing the chip mounting surface area may be not of highest relevance for wide bandgap chips. However, heat removal may be of utmost importance for wide bandgap semiconductor devices. Thus, maximizing heat dissipation by increasing the back side area of a carrier for such wide bandgap components may be particularly advantageous in exemplary embodiments.

An exemplary embodiment provides a possibility of heat sink extension by increasing a horizontal back side area in comparison with a horizontal component-sided area of a carrier, such as a die pad. Such an extension of the area of the package facing a heat sink may enhance heat removal to thereby improve or even optimize thermal resistance characteristics.

Advantageously, a taper in a sidewall of a die pad-type carrier may be created by stamping, coining or another appropriate method. Further advantageously, the tapering angle may be flexibly adjusted in order to enlarge the size of the heat sink, for instance for making the base of the carrier bigger than its top surface.

In an embodiment, the enlarged area of the heat sink may make the exposed area of the heat sink bigger, resulting in better thermal resistance performance. In particular, the heat sink area may be rendered bigger than the component-sided size of the die pad. This may have a positive impact on the conventional issue of anti-mold flash consuming space and a corresponding reduction of the effective exposed heat sink area. Furthermore, it may be advantageous that the tapered heat sink gives additional space for mold lock and/or mold flash to build up, thereby providing in particular a bigger margin for the anti-mold flash. Additionally, benefits of exemplary embodiments may include a bigger margin for mold build up, and a bigger sized heat sink with more exposed area giving better performance in terms of thermal resistance.

Exemplary applications of exemplary embodiments are electrical charging devices, onboard charging devices, solar devices, wind power devices, or trains.

FIG. 1 illustrates a schematic cross-sectional view of a package 100 according to an exemplary embodiment.

The package 100 comprises a carrier 102, which is here embodied as a die pad. The carrier 102 may be formed as a die pad of a leadframe structure, i.e. as a patterned metal plate. Said patterning may include defining the shape of sidewalls 120 of the carrier 102 and may be accomplished preferably by punching and/or coining. For example, the carrier 102 can be made of copper and/or aluminum or other applicable materials. Consequently, the carrier 102 may be electrically conductive and thermally conductive.

As shown, the carrier 102 has a horizontal component-sided area 104 on a front side 106. In the illustrated embodiment, the horizontal component-sided area 104 is a planar area at a continuously constant vertical level. Thus, the horizontal component-sided area 104 corresponds to a substantially planar or flat upper main surface of the structured plate-shaped carrier 102. Hence, component-sided area 104 is oriented horizontally and constitutes the side of the carrier 102 which is configured for carrying one or more electronic components 108, as described below in further detail.

Furthermore, the carrier 102 comprises a lower main surface via which heat is removed, which heat is generated during operation of package 100. Said lower main surface of the carrier 102 is denoted as horizontal back side area 112 and may function as a heat removal area in the shown embodiment. Horizontal back side area 112 faces away from horizontal component-sided area 104. In the illustrated embodiment, the horizontal back side area 112 is a planar area at a continuously constant vertical level. A skilled person will understand that, although the vast majority of the bottom surface of the die pad-type carrier 102 may be flat or planar, there may be some minor regions of the die pad's bottom surface having grooves, recesses, patterns, etc., for example for holding solder when soldering on a PCB, or thermally conductive glue when attaching a heat sink. According to FIG. 1, horizontal component-sided area 104 and horizontal back side area 112 may both be substantially planar and may extend parallel to each other.

As shown as well in FIG. 1, an electronic component 108 is mounted on a central part of the horizontal component-sided area 104 of the carrier 102. For instance, the electronic component 108 may be soldered or sintered on the top side of the carrier 102. For example, the electronic component 108 may be a semiconductor chip, preferably a power semiconductor chip. For instance, said semiconductor chip may be manufactured in wide bandgap semiconductor technology, for instance in silicon carbide or gallium nitride technology. For such kind of electronic components 108, efficient removal of heat generated by said electronic component 108 during operation of package 100 is of utmost advantage for the performance of the package 100 as a whole.

Still referring to FIG. 1, an encapsulant 110 encapsulates the entire electronic component 108 and only a part of the carrier 102. More specifically, the encapsulant 110 is provided so as to expose the entire horizontal back side area 112 on back side 114 of the carrier 102 opposing said front side 106. Apart from the exposed horizontal back side area 112, all other surface portions of the carrier 102 may be covered by encapsulant 110 or electronic component 108. Preferably, encapsulant 110 is a mold compound. Such a mold compound may comprise a matrix of epoxy resin filled with filler particles (for instance aluminum oxide or aluminum nitride particles) for fine-tuning the properties of encapsulant 110, in particular its thermal conductivity. Additionally, the mold compound may comprise one or more additives. The mold compound-type encapsulant 110 may be electrically insulating for providing a high electric reliability of package 100. However, a mold compound-type encapsulant 110 may have a limited thermal conductivity, so that efficient heat removal out of package 100 may be an issue.

In the embodiment of FIG. 1, heat generated by electronic component 108 during operation of the package 100 is dissipated predominantly via the carrier 102 and more specifically via the exposed horizontal back side area 112 thereof. Highly advantageously, the carrier 102 and in particular the design of its sidewalls 120 may be selected so that a size S (shown only schematically in FIG. 1 and denoting an area in square centimeters) of the exposed horizontal back side area 112 is larger than a size L (shown only schematically in FIG. 1 and denoting an area in square centimeters) of the horizontal component-sided area 104. Thus, the surface area of the exposed horizontal back side area 112 may have a size S exceeding the size L of the horizontal component-sided area 104, i.e. S>L. To put it shortly, this may be achieved by exposing the entire bottom main surface of carrier 102 and by a tapering design of the sidewalls 120 of the carrier 102. Consequently, the exposed surface area of the carrier 102 via which heat generated by encapsulated electronic component 108 can be dissipated out of package 100 into an environment thereof can be increased by adjusting the design of carrier 102 so that S>L. By taking this measure, the amount of heat which can be dissipated via exposed horizontal back side area 112 can thus be increased. In addition, heat spreading over a certain angular range may be enhanced by the sidewalls 120 tapering from exposed horizontal back side area 112 towards horizontal component-sided area 104. As a result, a package 100 with excellent thermal reliability and outstanding performance may be obtained without compromising on electric reliability. All these advantages can be achieved by a very simple measure, i.e. by a slanted design of sidewalls 120 of carrier 102.

Still referring to FIG. 1 and in particular a detail 150, the carrier 102 tapers in a thickness direction 118 from the back side 114 towards the front side 106. Said thickness direction 118 also corresponds to a stacking direction along which electronic component 108 is stacked on carrier 102. As shown, the tapering sidewall 120 of the carrier 102 has a slanted straight shape. Detail 150 shows a tapering angle β of sidewall 120 of the carrier 102 relative to the vertical direction 122 (which corresponds according to FIG. 1 to thickness direction 118). Preferably, said tapering angle β is in a range from 5° to 30°, for instance 10°. With the mentioned angular range, it may be ensured that the enlargement of the exposed horizontal back side area 112 is sufficiently pronounced, while simultaneously manufacturing artefacts, such as burrs, may be prevented in the corner regions of the carrier 102.

For example, a difference between a diameter (corresponding to the horizontal span of size S according to FIG. 1) of the exposed horizontal back side area 112 and a diameter (corresponding to the horizontal span of size L according to FIG. 1) of the horizontal component-sided area 104 is at least 0.5 mm and not more than 5 mm. The additional amount of heat is then significant, while well-defined corners of the (in the shown cross-sectional view trapezoid) carrier 102 may be ensured. For example, the diameter of the exposed horizontal back side area 112 may be 14 mm, whereas the diameter of the horizontal component-sided area 104 may be 13 mm. If the carrier 102 has a square shape, the respective diameter may be the side length of the square. If the carrier 102 has a rectangular shape, the respective diameter may be the longer side length of the square. If the carrier 102 has a circular shape, the respective diameter may be the double radius of the circle.

Carrier 102 may have a vertical thickness D in a range from 200 μm to 2 mm. A thick carrier 102, for instance having a thickness of at least 1 mm, in combination with the tapering sidewalls 120 may be capable of removing a high amount of heat and may also support efficient heat spreading. In the shown embodiment, the thickness D may be 2 mm.

FIG. 2 illustrates a flowchart 200 of a method of manufacturing a carrier 102 according to an exemplary embodiment. The reference signs used for the following description of said manufacturing method relate to the embodiments of FIG. 1 and FIG. 3.

Referring to a block 202, the method comprises providing the carrier 102 with a front side 106 with a horizontal component-sided area 104.

Referring to a block 204, the method comprises providing the carrier 102 with a back side 114 opposing said front side 106 and having a horizontal back side area 112.

Referring to a block 206, the method comprises forming a size S of the horizontal back side area 112 larger than a size L of the horizontal component-sided area 104.

FIG. 3 illustrates a schematic cross-sectional view of a package 100 according to another exemplary embodiment. Although not shown in FIG. 3, one or more electronic components 108 may be mounted on a horizontal component-sided area 104 of carrier 102.

The embodiment according to FIG. 3 differs from the embodiment according to FIG. 1 in particular in that, according to FIG. 3, size H of the exposed portion of the horizontal back side area 112 is the same as size L of the horizontal component-sided area 104 (H=L). In this embodiment, an additional bottom-sided edge region with a horizontal extension B is present for forming an anti-flash profile in form of a retracted lateral section 126, as described below. As shown, the dimensions of FIG. 3 can be described by the equations S=H+2B and S>L. In FIG. 3, the bottom main surface of carrier 102 has a circumferential step 124 at the back side 114 to thereby form retracted lateral section 126 surrounding a protruding central area 197.

According to FIG. 3, the carrier 102 tapers in a thickness direction 118 from the back side 114 towards the front side 106 with an outwardly oriented spike 116 in a straight tapering sidewall 120. Said outwardly oriented spike 116 may contribute to mold interlocking. Thus, said spike 116 may mechanically anchor the carrier 102 in the encapsulant 110 for improving the structural integrity and thus mechanical reliability of package 100.

Moreover, the embodiment according to FIG. 3 differs from the embodiment according to FIG. 1 in particular in that, according to FIG. 3, the carrier 102 has step 124 at the back side 114 between the exposed main heat removal area of the horizontal back side area 112 and retracted lateral section 126 surrounding the exposed main heat removal area of the horizontal back side area 112. For example, retracted lateral section 126 may have horizontal extension, B, in a range from 0.1 μm to 0.5 μm. This is best seen in a detail 152 in FIG. 3. The circumferentially closed step 124 may form an anti-flash profile tackling mold flash at the bottom side of package 100. Although only a single circumferentially closed step 124 is shown in FIG. 3, it may also be possible to form an anti-flash profile by a plurality of steps (for instance forming a stairway-shape) at the bottom main surface of the carrier 102 and thus adjacent to exposed protruding central area 197 of horizontal back side area 112.

In the embodiment of FIG. 3, the exposed bottom surface area of the carrier 102 is the same as (but may also be larger than) the top surface area of the carrier 102. Apart from an improved thermal performance of package 100, the embodiment of FIG. 3 may also ensure that even if the bottom of the carrier 102 is covered with mold residues, a good thermal dissipation may still be ensured.

FIG. 4 illustrates a schematic cross-sectional view of a carrier 102 of a package 100 according to an exemplary embodiment. To put it shortly, FIG. 4 shows the carrier 102 of FIG. 1 without encapsulant 110 and without electronic component 108. Heat sink enlargement may be achieved by the tapering sidewalls 120. A die pad top corresponds to the horizontal component-sided area 104. A heat sink attachment surface corresponds to the heat removal surface 112, which remains exposed even after encapsulation.

FIG. 5 illustrates a schematic cross-sectional view of a carrier 102 of a package 100 according to another exemplary embodiment. FIG. 5 shows the carrier 102 of FIG. 3 without encapsulant 110.

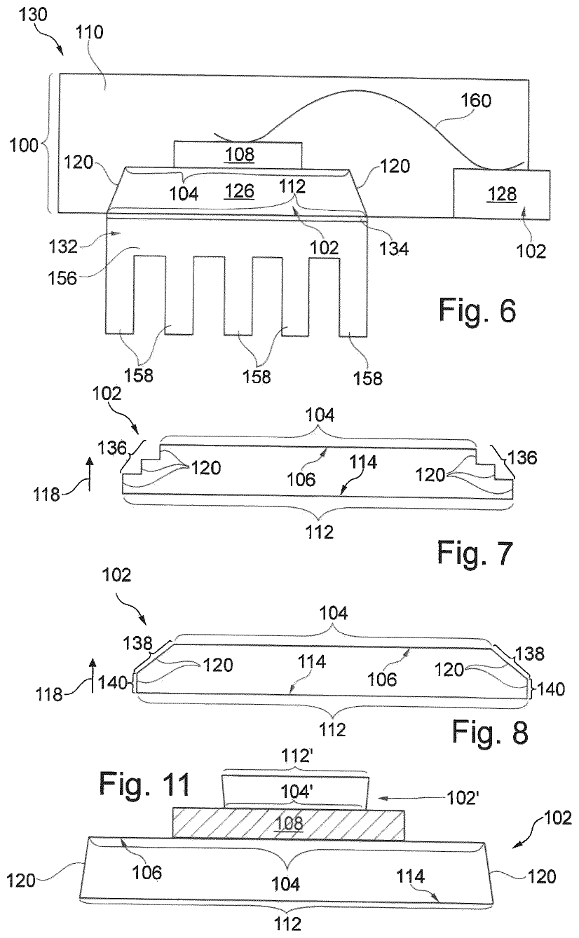

FIG. 6 illustrates a cross-sectional view of an electronic device 130 comprising a package 100 according to an exemplary embodiment and being assembled with a mounting structure 132.

Package 100 according to FIG. 6 comprises a metallic carrier 102 which comprises a die pad 125, on which an electronic component 108 is arranged (for instance soldered or sintered). As a further constituent in the embodiment of FIG. 6, metallic carrier 102 comprises a separate lead section 128 which is electrically coupled with the electronic component 108 by an electrically conductive connection structure 160. For example, electrically conductive connection structure 160 may be a bond wire or a clip.

A mold-type encapsulant 110 fully encapsulates the electronic component 108 and the electrically conductive connection structure 160 and partially encapsulates the die pad 125 and the lead section 128. By an exposed portion of the lead section 128, electric signals and/or electric power may be conducted between an exterior of package 100 and the electronic component 108. Die pad 125 of FIG. 6 is constructed substantially as described above for carrier 102 referring to FIG. 1.

As shown, the mounting structure 132 is mounted below the horizontal back side area 112 of the die pad 125. In the shown embodiment, the mounting structure 132 comprises a heat sink which is attached to a thermally conductive and electrically insulating layer 134 being arranged between the mounting structure 132 and the exposed horizontal back side area 112 of the package 100. For instance, the thermally conductive and electrically insulating layer 134 may be a thermal interface material (TIM). The heat sink forming mounting structure 132 may be made of a thermally highly conductive material, such as copper or aluminum. The heat sink may comprise a base plate 156 which may be attached directly to the thermally conductive and electrically insulating layer 134. A plurality of mutually spaced cooling fins 158 may be attached to the base plate 156 or may be integrally formed with base plate 156. By this construction, heat generated by encapsulated electronic component 108 of package 100 may be dissipated and spread via carrier 102 with its tapering sidewalls 120, thermally conductive and electrically insulating layer 134 and heat sink-type mounting structure 132 towards an environment of the electronic device 130.

In another embodiment (not shown), mounting structure 132 may be a printed circuit board or an insulated metal substrate, or any other kind of mounting base. In such an embodiment, the mounting structure 132 may be directly solder connected with carrier 102 (without thermally conductive and electrically insulating layer 134 in between).

FIG. 7 illustrates a schematic cross-sectional view of a carrier 102 of a package 100 according to another exemplary embodiment.

The embodiment of FIG. 7 differs from the embodiment of FIG. 4 in particular in that, according to FIG. 7, the sidewalls 120 of the carrier 102 have a stepped profile 136 narrowing from the back side 114 towards the front side 106. Descriptively speaking, the plurality of steps of the stepped profile 136 form a stair-shaped structure leading to an increase of the horizontal back side area 112. Furthermore, the multiple steps may interlock with encapsulant material, thereby improving the mechanical integrity of a package 100 formed on the basis of the carrier 102 of FIG. 7.

FIG. 8 illustrates a schematic cross-sectional view of a carrier 102 of a package 100 according to another exemplary embodiment.

The embodiment of FIG. 8 differs from the embodiment of FIG. 4 in particular in that, according to FIG. 8, a first part 138 of the sidewall 120 tapers in the thickness direction 118 and a connected second part 140 of the sidewall 120 extends vertically along the thickness direction 118. The first part 138 may lead to an increase of the horizontal back side area 112. The second part 140 may suppress formation of undesired burrs at a bottom side of carrier 102.

FIG. 9 illustrates a schematic cross-sectional view of a package 100 according to another exemplary embodiment. In this embodiment, the horizontal back side area 112 is fully encapsulated within the encapsulant 110.

The embodiment according to FIG. 9 differs from the embodiment according to FIG. 1 in particular in that, according to FIG. 9, horizontal back side area 112 is arranged inside encapsulant 110. The package type of FIG. 9 can be denoted as a full pack. Carrier 102 is fully embedded within encapsulant 110 according to FIG. 9.

FIG. 10 illustrates a schematic cross-sectional view of a package 100 according to another exemplary embodiment. In this embodiment, an interposer 199 is provided on the horizontal back side area 112 of the carrier 102 and is exposed beyond the encapsulant 110.

The embodiment according to FIG. 10 differs from the embodiment according to FIG. 9 in particular in that, according to FIG. 10, an interposer 199 is arranged between horizontal back side area 112 and a bottom-sided exterior of the package 100. In other words, interposer 199 may be exposed from the encapsulant 110 for promoting heat removal out of package 100. For example, interposer 199 may be a DAB substrate, an IMS substrate, etc. Although not shown in FIG. 10, interposer 199 may comprise a central ceramic sheet covered on both opposing main surfaces thereof by continuous or patterned metal layers, for instance made of copper or aluminum.

FIG. 11 illustrates a schematic cross-sectional view of parts of a package 100 according to an exemplary embodiment, wherein a carrier 102′ (for example, but not necessarily, an additional carrier) is configured as a clip.

More specifically, the portion of package 100 shown in FIG. 11 comprises a bottom-sided carrier 102 embodied as a die pad on which semiconductor die-type electronic component 108 is mounted. Bottom-sided carrier 102 can be embodied as described above referring to FIG. 1 to FIG. 10, wherein a configuration according to FIG. 1 is shown in FIG. 11. On an opposing other main surface of the electronic component 108, a further carrier 102′ is mounted which is embodied as a clip.

As shown, the further carrier 102′ has a horizontal component-sided area 104′ on a main surface facing electronic component 108 and being denoted as front side of the further carrier 102′. Furthermore, the further carrier 102′ comprises an opposing other main surface, denoted as back side, via which heat is removed, which heat is generated during operation of package 100 by electronic component 108. Said opposing other main surface of the further carrier 102′ is denoted as horizontal back side area 112′. Horizontal back side area 112′ faces away from horizontal component-sided area 104′. As shown in FIG. 11, sidewalls of further carrier 102′ extending from the horizontal component-sided area 104′ to the horizontal back side area 112′ taper towards electronic component 108. Correspondingly, a size of the horizontal back side area 112′ is larger than a size of the horizontal component-sided area 104′ of the clip. Thus, the slanted sidewall shape of the clip contributes to heat removal away from electronic component 108.

Hence, the die pad (see reference sign 102) and/or the clip (see reference sign 102′) may have the feature of a slanted side wall. The manufacturing of a die pad (for instance from a leadframe) or a clip (for instance from a clip frame) can be carried out correspondingly. The heat paths of die pad and clip may be identical, i.e. from the heat source in form of electronic component 108 to a heat sink (not shown in FIG. 11).

Although die pad-type carrier 102 and clip-type further carrier 102′ are both shown in FIG. 11, also embodiments are possible in which only the clip and not the die pad is manufactured with slanted sidewalls according to the embodiments described above. In particular, a clip-type carrier 102′ can be formed with the geometry of any of the die pad-type carriers 102 as described in any of the above described embodiments.

It should be noted that the term “comprising” does not exclude other elements or features and the “a” or “an” does not exclude a plurality. Also, elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. A leadframe, comprising:
a carrier for carrying an electronic component of a package,
a plurality of leads,
wherein the carrier comprises:
a front side being provided with a horizontal component-sided area; and
a back side opposing said front side and being provided with a horizontal back side area;
wherein a size of the horizontal back side area is larger than a size of the horizontal component-sided area,
wherein the carrier consists of a single part of metal.

2. The leadframe according to claim 1, wherein the carrier and the plurality of leads are made from a sheet-like metal plate.

3. The leadframe according to claim 1, wherein the carrier is a die pad.

4. The leadframe according to claim 1, wherein at least part of a sidewall of the carrier tapers in a thickness direction from the back side towards the front side.

5. The leadframe according to claim 4, wherein the at least partially tapering sidewall of the carrier has a straight shape.

6. The leadframe according to claim 4, wherein a first part of the sidewall tapers in the thickness direction and a connected second part of the sidewall extends vertically along the thickness direction.

7. The leadframe according to claim 4, wherein a tapering angle (B) of the sidewall of the carrier relative to a vertical direction is at least 5°.

8. The leadframe according to claim 1, wherein at least part of a sidewall of the carrier has a stepped profile narrowing from the back side towards the front side.

9. The leadframe according to claim 1, wherein the carrier has a step at the back side to thereby form a retracted lateral section surrounding a protruding central area.

10. A package, which comprises:
a plurality of leads;
a carrier;
an electronic component mounted on the carrier;
an encapsulant encapsulating at least part of the electronic component and at least part of the carrier,
wherein the carrier comprises:
a front side being provided with a horizontal component-sided area; and
a back side opposing said front side and being provided with a horizontal back side area,
wherein a size of the horizontal back side area is larger than a size of the horizontal component-sided area,
wherein the carrier consists of a single part of metal, and
wherein the horizontal back side area is partially or entirely exposed beyond the encapsulant.

11. The package of claim 10, wherein the carrier is a die pad and its horizontal back side area is partially or entirely exposed beyond the encapsulant.

12. The package of claim 10, wherein the carrier is a clip, the package is a top-sided cooling package, and the horizontal back side area of the carrier is partially or entirely exposed beyond the encapsulant.

13. The package of claim 10, wherein the carrier is a die pad, and its horizontal back side area is fully encapsulated within the encapsulant, and the package further comprises an interposer on the horizontal back side area of the carrier and being exposed beyond the encapsulant.

14. The package of claim 10, wherein a size of an area of the horizontal back side area being exposed beyond the encapsulant is the same as or is larger than the size of the horizontal component-sided area, and wherein the electronic component is a semiconductor power chip.

15. An electronic device, comprising:
a package according to claim 10; and
a mounting structure mounted on, below or above the horizontal back side area.

16. The electronic device according to claim 15, comprising at least one of the following features:
wherein the mounting structure comprises a heat sink or a mounting base, for example a printed circuit board or an insulated metal substrate; and
the electronic device further comprises a thermally conductive and electrically insulating layer between the mounting structure, formed as a heat sink, and the horizontal back side area being at least partially exposed beyond the encapsulant.
